(19) United States
(12) Patent Application Publication
(10) Pub. No.: US 2012/0292506 A1
(43) Pub. Date: Nov. 22, 2012

(54) SAMPLE OBSERVATION METHOD USING ELECTRON BEAMS AND ELECTRON MICROSCOPE

(75) Inventors: Natsuki Tsuno, Saitama (JP); Hiroshi Makino, Mito (JP); Makoto Suzuki, Hitachinaka (JP); Yusuke Ominami, Hitachinaka (JP)

(73) Assignee: HITACHI HIGH-TECHNOLOGIES CORPORATION, Tokyo (JP)

(21) Appl. No.: 13/508,774

(22) PCT Filed: Nov. 8, 2010
(86) PCT No.: PCT/JP2010/069845

§ 371 Date: May 9, 2012

(30) Foreign Application Priority Data
Nov. 13, 2009 (JP) 2009-259980

(51) Int. Cl. H01J 37/26

(52) U.S. Cl. 250/307; 250/310

(57) ABSTRACT

A disclosed method for observing the structure and characteristics of a specimen by an electron microscope realizes high-density charge accumulation on a specimen and improves the quality of voltage contrast images. For structural observation of a specimen and evaluation of its electrical characteristic using an electron beam, charging the specimen is performed. In this charging process, high-density charge accumulation on the specimen is achieved by irradiating the specimen with an electron beam set to have injection energy that falls within an injection energy band for which high charging efficiency is attained during electron beam irradiation and changing irradiation energy, while maintaining the injection energy.

### TECHNICAL FIELD

The present invention relates to a microscope technique for observing a configuration of a specimen using an electron beam and, particularly, to a technique for processing of charging the surface of a specimen.

### BACKGROUND ART

As a microscope that can magnify and observe a specimen, there is an electron microscope using an electron beam and it is used for detailed observation of the specimen surface and dimension measurement. A microscope that focuses an electron beam accelerated by an accelerating voltage applied to an electron source by means of an electron lens and scans the focused electron beam (primary electrons) over a specimen is called a scanning electron microscope. Energy of electron beam irradiation on a specimen is determined by a difference between an accelerating voltage applied to the electron source and a voltage that is applied to the specimen. This energy is called irradiation energy that is determined independently of the specimen. Meanwhile, if the surface of a specimen is charged, energy when an electron beam is incident on the specimen is determined by a difference between irradiation energy and a charging voltage of the surface of the specimen. This energy is called injection energy that varies depending on the charging voltage of the surface of the specimen. The scanning electron microscope detects secondary electrons that are ejected from a specimen irradiated with primary electrons and makes up an image. The amount of signals of detected secondary electrons changes with a voltage distribution over the specimen and forms a contrast reflecting the voltage distribution (which is referred to as voltage contrast). An example of observation using the voltage contrast is determining whether a structure is conducting or non-conducting by the voltage contrast. Such a method of discriminating between conduction and no conduction using the voltage contrast is used as a means for evaluating an electric characteristic of a semiconductor device or the like by the scanning electron microscope. In order to improve the quality and stability of voltage contrast images, it is needed to increase the charging voltage of a specimen and control the voltage to be stable.

As a method for control of charging the surface of a specimen, there is a method that accumulates charges on the surface of the specimen by electron beam irradiation. This charge accumulation is determined by a yield of secondary electrons ejected from the specimen. The yield of ejected secondary electrons versus the number of irradiation electrons is defined by the number of secondary electrons/the number of primary electrons and it is called a secondary electron yield δ. If the secondary electron yield δ is 1 or more, the specimen surface is positively charged; if less than 1, it is negatively charged. As shown in FIG. 2, the secondary electron yield δ changes depending on injection energy E of primary electrons. By making an appropriate use of a low injection energy range for which δ is less than 1 (0<E<E1) and a high injection energy range for which δ is 1 or more (E1<E), the polarity of charging can be controlled.

As a method for control of, particularly, negative charging, there is a method that controls irradiation energy of primary electrons, as described in Patent Literature 1. In Patent Literature 1, it is disclosed that, if a specimen is irradiated by low irradiation energy, for example, 20 V, less than E1 as shown in FIG. 2, the specimen is negatively charged because of a secondary electron yield of less than 1 and charging reaches an equilibrium state, when the specimen surface has been charged to a negative voltage enough to repel primary electrons. Stated differently, if a specimen is irradiated by constant low irradiation energy less than E1, negative charging of the specimen progresses and injection energy attenuates with the progress of the negative charging. In a state that the injection energy becomes approximately 0 (irradiation energy of primary electrons=charging voltage of the specimen), the specimen is no longer irradiated with the electron beam, which, thus, creates the equilibrium state. The method described in Patent Literature 1 controls a voltage that produces negative charging by irradiation energy of primary electrons.

Meanwhile, in the case of processing of negative charging by low irradiation energy, i.e., injection energy less than E1 mentioned above, it is difficult to determine injection energy, because injection energy changes depending on initial charging of a specimen. A method that solves this problem is disclosed in Patent Literature 2. The following method is disclosed: if the limit of charging of a specimen is, for example, +100 V, the irradiation energy of the electron beam is first set at +100 V, i.e., the charging limit value and the specimen is irradiated by +100 V, followed by making a stepwise change of the irradiation energy up to a target voltage. In this method, electron beam irradiation is performed with several levels of irradiation energy so as to include a possible initial charging voltage and, thus, the charging method not affected by initial changing of the specimen is disclosed.

### CITATION LIST

### Patent Literature

Patent Literature 1: Japanese Patent Application Laid-Open Publication No. 2000-208579
Patent Literature 2: Japanese Patent Application Laid-Open Publication No. 2006-86506

### SUMMARY OF INVENTION

### Technical Problem

In the related-art technique for charging with injection energy for which the above-mentioned secondary electron yield δ is less than 1 (E<E1), a charging voltage is determined by irradiation energy, as noted previously. However, the following problem exists: if a target voltage for charging is equal to or more than E1, δ becomes 1 or more and negative charging for E1 or more cannot be performed.

Even if the target charging voltage is set to be less than E1, depending on a specimen, negative charging may not progress up to a state that primary electrons are repelled. This phenomenon closely relates to interaction between the electron beam and the specimen. When the specimen is irradiated with an electron beam having a relatively high injection energy (e.g., in the order of 50 eV to 100 eV) even in the range of injection energy less than E1, the electron beam loses energy, while generating electron-hole pairs and accumulates charges inside the specimen. When the injection energy further decreases (e.g., less than 50 eV), the interaction between the electron beam and the specimen becomes weak and, accordingly, the electron-hole pairs become hard to generate. Hence, the energy of the incident electron beam becomes hard to lose. Consequently, a phenomenon in which, in a low injection energy range, e.g., less than 50 eV, a penetration depth, that is, a depth to which the electron beam accumulates charges, becomes deeper is reported (M. P. Seah and W. A. Dench, Surf. Interface Anal., vol. 1, No. 1, 1979). Especially for a thin film specimen or the like, even if the specimen is irradiated with an electron beam having low injection energy for which the penetration depth becomes larger than the thickness of the thin film, the irradiation electron beam flows out via a specimen holder as a leak current and, thus, charges cannot be accumulated in the specimen and charging capability decreases. In consequence, negative charging does not progress up to the state that primary electrons are repelled and, thus, there is a problem in which high-density charge accumulation providing a large charging voltage is difficult.

An object of the present invention is to provide a method for observing a specimen using an electron beam and an electron microscope to address the above-noted problems and to improve the capability of charging the surface of a specimen, increase the stability of charging control, and improve the quality of voltage contrast images.

### Solution to Problem

A method for observing a specimen using an electron beam, according to the present invention, is including irradiating a specimen with an electron beam having an injection energy band for which high charging efficiency is attained during electron beam irradiation in a low injection energy range. This method takes advantage of the fact that an injection energy band producing significant charge accumulation in a surface layer of a specimen exists in a low injection energy range for which interaction with the specimen is less and charge effluence from the specimen accounts for a large proportion. In the surface layer of a specimen, there are a large number of dangling bonds, structural defects, etc. and charges are easy to accumulate. The method is to determine an injection energy band producing significant charge accumulation in the surface layer and perform charging by irradiation with an electron beam having the injection energy band. According to this method, it is possible to prevent charge effluence which would occur during electron beam irradiation and to improve the capability of charging a specimen.

The method for observing a specimen using an electron beam, according to the present invention, also includes irradiating a specimen with an electron beam and by injection energy that falls within an injection energy band for which high charging efficiency is attained during electron beam irradiation and changing irradiation energy of the electron beam up to a target voltage for charging, while maintaining the injection energy. In this method, a specimen is charged to a desired voltage by changing the irradiation energy of the electron beam up to a target voltage for charging, while maintaining the injection energy falling within the injection energy band for which high charging efficiency is attained. In this method, an injection energy band that is used does not depend on a target voltage for charging and, thus, there is not a limit of charging voltage depending on E1 in FIG. 2 above. Because the method changes the irradiation energy, while maintaining the injection energy falling within the injection energy band, the charging efficiency during electron beam irradiation by irradiation energy is high and charging with high accuracy can be performed. According to this method, it is possible to control a charging voltage, while using an electron beam with a high charging capacity, and charges can be accumulated at higher density than in the past.

The method for observing a specimen using an electron beam, according to the present invention, also includes changing irradiation energy of the electron beam up to a target voltage for charging, while monitoring for a leak current during electron beam irradiation. According to this method, it is possible to monitor that a specimen is irradiated by injection energy for which high charging efficiency is attained by monitoring for a leak current when changing the irradiation energy of the electron beam and, thus, charging with high reproducibility and stability can be performed.

Here, it is included that a speed of changing irradiation energy of the electron beam up to a target voltage (=target voltage/time taken for change) is set equal to or less than an upper limit value calculated from electrostatic capacitance of the specimen and an irradiation current. Because charging speed differs by specimen, particularly, it is important to set up the speed of changing the irradiation energy per specimen in order to maintain the injection energy of the electron beam falling within the injection energy band for which no charge effluence occurs.

The method for observing a specimen using an electron beam, according to the present invention, also includes charging a specimen having a large charging area by scanning the specimen with the electron beam and a speed of scanning the specimen with the electron beam is set depending on a speed of changing the irradiation energy. When charging an area wider than an irradiation area of the electron beam, it is required to set up the scanning speed so that the speed of changing the irradiation energy is equal to or less than a speed at which the electron beam passes across the same area. According to this method, charging an area wider than an electron beam irradiation area can be performed.

Alternatively, a method for observing a specimen using an electron beam, according to the present invention, includes: irradiating the specimen with an electron beam having first injection energy that falls within an injection energy band for which high charging efficiency is attained during electron beam irradiation; scanning the specimen with the electron beam having the first injection energy; changing irradiation energy of the electron beam by a voltage pitch that maintains the first injection energy; irradiating again the specimen with the electron beam and by the changed irradiation energy of the electron beam; scanning again the specimen with the electron beam having the first injection energy; and charging the specimen having a large charging area up to a target voltage for charging by repeating changing irradiation energy of the electron beam, irradiating the specimen with the electron beam, and scanning the specimen. According to this method, high-density charging of a specimen having a larger charging area can be performed with ease.

Here, it is included in the present invention that the injection energy band and injection energy of the electron beam is an injection energy range from 0 to 10 eV.

It is also included in the present invention that the charging efficiency is equal to or more than 0.8.

An electron microscope of the present invention includes an electron gun that emits an electron beam; an electron optical system that irradiates a specimen with the electron beam; a specimen holder that holds the specimen; a detector that detects electrons ejected from the specimen; a second electron source for which irradiation energy can be controlled; a waveform generator that generates a changing waveform of irradiation energy; and an irradiation energy controller that changes irradiation energy of an electron beam of the second electron source, while maintaining injection energy that falls within an injection energy band for which high charging efficiency is attained during electron beam irradiation, based on the changing waveform of irradiation energy.

Alternatively, an electron microscope of the present invention includes an electron gun that emits an electron beam with controlled irradiation energy; an electron optical system that irradiates a specimen with the electron beam; a specimen holder that holds the specimen; a detector that detects electrons ejected from the specimen; a charging efficiency measurement device that measures charging efficiency of the electron beam; a waveform generator that generates a changing waveform of irradiation energy; and an irradiation energy controller that changes irradiation energy of the electron beam, while maintaining injection energy that falls within an injection energy band for which high charging efficiency is attained during electron beam irradiation, based on the changing waveform of irradiation energy and depending on a measurement result of the charging efficiency.

Alternatively, an electron microscope of the present invention includes an electron gun that emits an electron beam; an electron optical system that irradiates a specimen with the electron beam; a specimen holder that holds the specimen; a detector that detects electrons ejected from the specimen; a second electron source for which irradiation energy can be controlled; a charging efficiency measurement device that measures charging efficiency of an electron beam from the second electron source; a waveform generator that generates a changing waveform of irradiation energy; and an irradiation energy controller that changes irradiation energy of an electron beam from the second electron source, while maintaining injection energy that falls within an injection energy band for which high charging efficiency is attained during electron beam irradiation, based on the changing waveform of irradiation energy and depending on a measurement result of the charging efficiency.

Alternatively, an electron microscope of the present invention includes an electron gun that emits an electron beam; an electron optical system that irradiates a specimen with the electron beam; a specimen holder that holds the specimen; a detector that detects electrons ejected from the specimen; an electron source divided into a plurality of elements to which steps of irradiation energy from initial irradiation energy up to a target voltage are applied in order; and a moving mechanism that causes relative movement of the specimen holder and the electron source at such a velocity as to maintain injection energy that falls within an injection energy band for which high charging efficiency is attained during electron beam irradiation.

### Advantageous Effects of Invention

According to the present invention, charging of a specimen by electron beam irradiation can be processed efficiently and it is, therefore, possible to improve the quality of voltage contrast images and to make an observation with high-quality images in electron microscope observation.

### BRIEF DESCRIPTION OF DRAWINGS

FIG. 1 is a structural diagram depicting an example of an electron microscope of the present invention.

FIG. 2 is a graph showing a relationship between injection energy and secondary electron yield.

FIG. 3 is a graph showing a relationship between injection energy and charging efficiency.

FIG. 4 is an explanatory diagram showing one example of a time chart of charging control of a first exemplary embodiment.

FIG. 5 is an explanatory diagram showing another example of a time chart of charging control of the first exemplary embodiment.

FIG. 6 is a flow diagram showing an example of a flow of observation involving a charging process for the first exemplary embodiment.

FIG. 7 is an explanatory diagram showing an example of the specimen charging capability of the charging process of the first exemplary embodiment.

FIG. 8 is a structural diagram depicting an example of a charging system of a second exemplary embodiment.

FIG. 9 is a graph showing a relationship between a slope of change in accelerating voltage and charging voltage.

FIG. 10 is a flow diagram showing an example of a flow for setting up a slope threshold of the second exemplary embodiment.

FIG. 11 is a diagram showing an example of a GUI that helps to set up charging conditions of the second exemplary embodiment.

FIG. 12 is a flow diagram showing an example of a flow of condition setting of a third exemplary embodiment.

FIG. 13 is a flow diagram showing an example of a flow of condition setting of a fourth exemplary embodiment.

FIG. 14 is a structural diagram depicting an example of an electron source for charging of a fifth exemplary embodiment.

### DESCRIPTION OF EMBODIMENTS

In the following, embodiments of the present invention will be described by way of the drawings.

### First Embodiment

In the present exemplary embodiment, descriptions are provided about a method and apparatus that accumulate charges on the surface of a specimen, using an electron beam with an injection energy band in which no charges flow out from the specimen during electron beam irradiation. As an electron microscope in the present exemplary embodiment, a scanning electron microscope is described by way of example. However, the present invention is not limited to the scanning electron microscope and can be carried out in any microscope using a charged particle beam for observing a charged specimen.

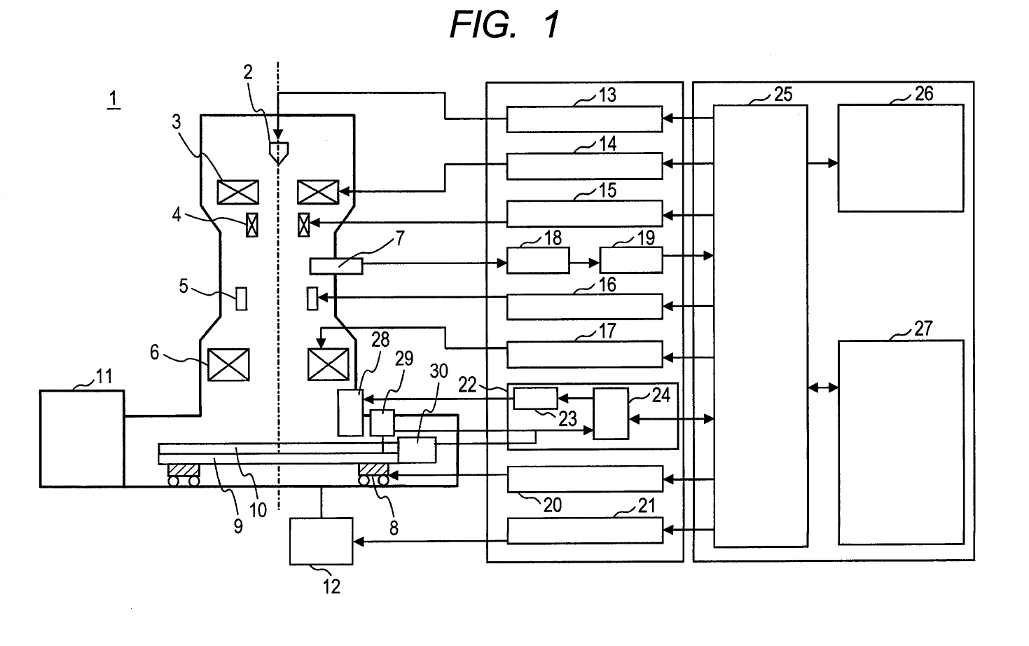

FIG. 1 depicts an example of a structure of the scanning electron microscope according to the present exemplary embodiment. The scanning electron microscope 1 is configured with an electron optical system, stage mechanism system, control system, specimen charging system, and operation system. The electron optical system is configured with an electron gun 2, a condenser lens 3, an alignment coil 4, a deflector 5, an objective lens 6, and a detector 7. The stage mechanism system is configured with an XYZ stage 8, a specimen holder 9, a specimen 10, a specimen transport unit 11, and an evacuation unit 12. The control system is configured with an electron gun controller 13, a condenser lens coil controller 14, an alignment coil controller 15, a deflection and scan signal controller 16, an objective lens coil controller 17, a detector controller 18, a detected signal processing unit 19, a stage controller 20, an evacuation controller 21, and a charging controller 22. The charging controller 22 is composed of an electron source controller 23 that can optionally change irradiation energy and a waveform generator 24 with regard to irradiation energy. Although there is the electron source controller 23, because irradiation energy is controlled by an accelerating voltage that is applied to an electron source 28 in the present invention, it may be possible to control a voltage that is applied to the specimen holder 9 or control an irradiation slope that is determined by a specimen and an electron beam irradiation direction. The operation system is configured with a control computer 25, a display unit 26, and a data storage unit 27. The specimen charging system is configured with an electron source for specimen charging 28, an ammeter 29 that measures a current flowing out from the specimen holder, and a Faraday cup 30 that measures an irradiation current. Although the electron source 28 is used, because charging with an electron beam is performed in the present exemplary embodiment, no limitation to the electron source 28 is intended and a charged particle beam source that enables specimen charging may be used. Although the electron source 28 capable of electron beam irradiation over a large irradiation area is used to charge a specimen at a high speed, the electron gun 2 comprised in the electron optical system may be used instead of the electron source for specimen charging 28. Although the present exemplary embodiment uses an arrangement in which accumulated charge characteristics during electron beam irradiation are measured by the ammeter, as a device that measures accumulated charges during electron beam irradiation other than the ammeter, a non-contact surface potential meter or an Auger electron probe to measure surface potential, an internal charge meter to measure a spatial charge quantity and position inside a specimen, etc. can be used.

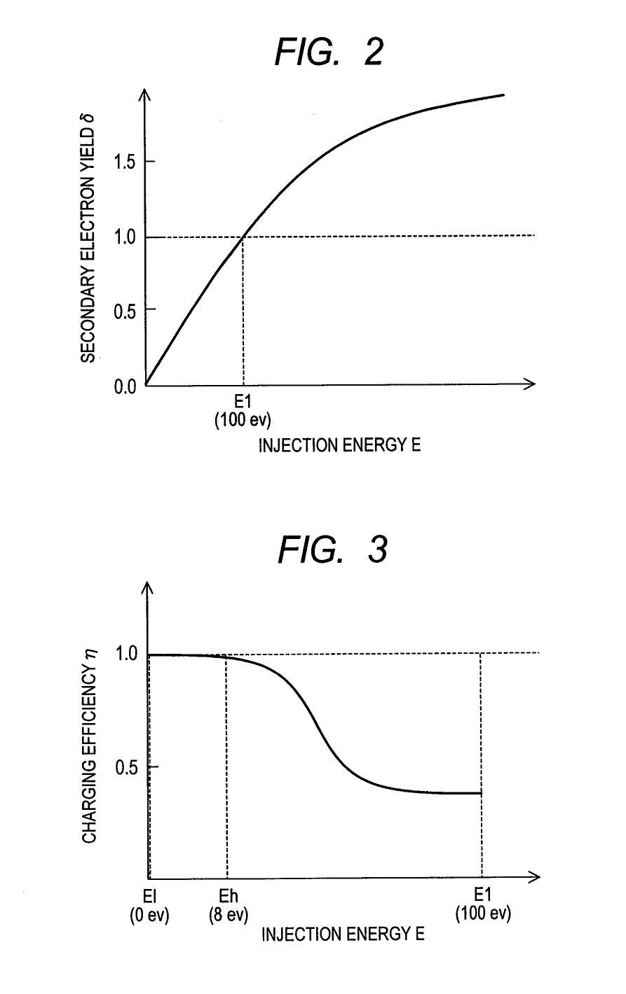

A method for processing of charging a resist film through the use of the apparatus structure of the present exemplary embodiment is described. FIG. 2 shows a relationship between injection energy and secondary electron yield δ. When performing negative charging, as for injection energy, it is needed to determine an injection energy band in which charge effluence is very few during electron beam irradiation within a range of injection energy less than E1 (E1=100 eV for the resist film used in the present exemplary embodiment) shown in FIG. 2. In the present exemplary embodiment, in determining an injection energy band charge in which effluence does not occur during electron beam irradiation, evaluation should be made in terms of charging efficiency η during electron beam irradiation. Charging efficiency η is expressed by equation (1).

Charging efficiency η=(irradiation current−leak current)/irradiation current (1)

The irradiation current is a current of an electron beam that arrives at a specimen position from the electron source for specimen charging 28 and can be measured by the ammeter 29 via the specimen holder, when the Faraday cup 30 is irradiated with the electron beam. The leak current is a flow of charges flowing out from the specimen, when the specimen 10 is irradiated with the electron beam, and can be measured by the ammeter 29 via the specimen holder, when the specimen 10 is irradiated with the electron beam from the electron source for specimen charging 28.

FIG. 3 shows a relationship between injection energy and charging efficiency η in a low injection energy range less than E1. The charging efficiency η is 1 between a lower limit value of injection energy El (=0 eV) and an upper limit value of injection energy Eh (=8 eV) and an injection energy band for which high charging efficiency is attained can be determined. Although a range for which the charging efficiency η is 1 is determined to be the injection energy band for which high charging efficiency is attained in the present exemplary embodiment, an allowable range of charging efficiency η can be set depending on the accuracy of a target voltage. In the present exemplary embodiment, injection energy of 5 eV is selected for use from the injection energy band for which high charging efficiency is attained.

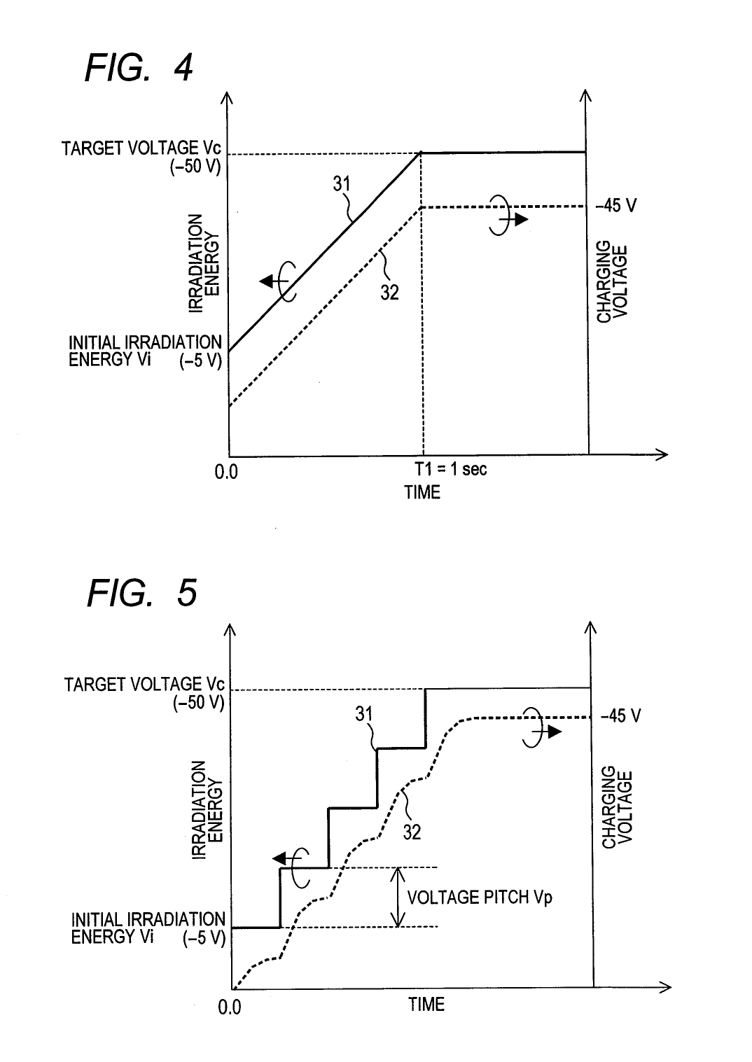

FIG. 4 shows a time chart 31 when irradiation energy is changed continuously. In FIG. 4, change of charging voltage 32 of a specimen is also shown. In the present exemplary embodiment, the target voltage Vc is set at −50 V and the irradiation energy is changed from initial irradiation energy Vi=−5 V to Vc=−50 V for one second, as shown in the time chart 31. At that time, charges are accumulated, while the injection energy of 5 eV is maintained, and the specimen can be charged up to −45 V.

FIG. 5 shows a time chart when a stepwise change of irradiation energy is made. Initial irradiation energy and a voltage pitch Vp of change need to be voltages within the range from El to Eh shown in FIG. 3. When voltage is changed by this voltage pitch Vp up to the target voltage Vc, the specimen is irradiated by energy within the range from El to Eh and, thus, charging at a high charging efficiency can be performed.

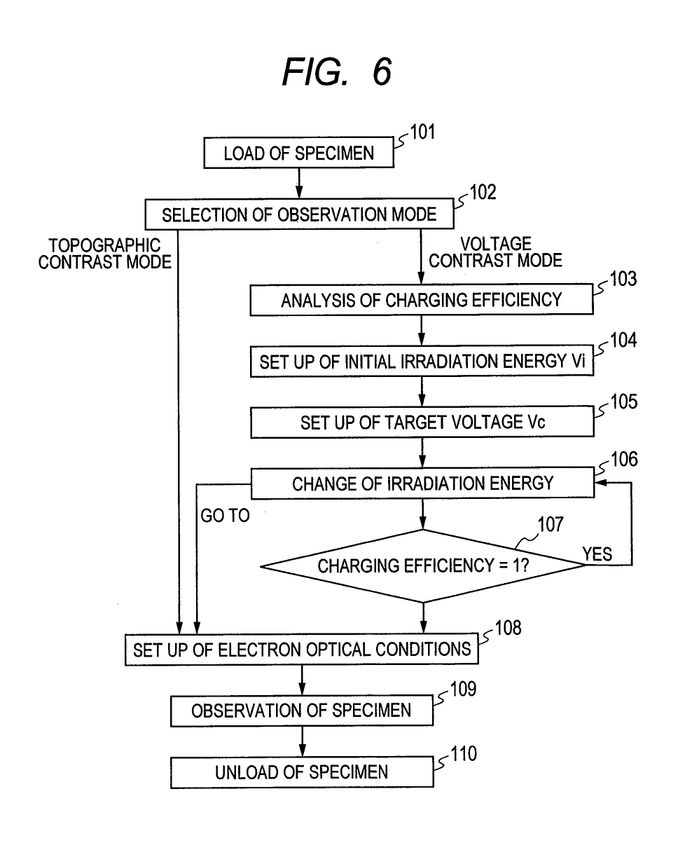

Then, a method for observing a specimen through the use of the above-described charging process is described according to a flowchart. The flowchart is shown in FIG. 6. A specimen 10 is carried by the specimen transport unit 11 and loaded into an observation chamber after being evacuated (step 101). If a voltage contrast observation mode is selected by selection of an observation mode, the specimen 10 is carried on the XYZ stage 8 to the specimen charging system (step 102). To set up injection energy for charging, analysis of a characteristic of charging efficiency versus injection energy as in FIG. 3 above is performed (step 103). Although the injection energy range for which the charging efficiency is 1 is used in the present exemplary embodiment, it is preferable that the charging efficiency is equal to or more than 0.8 in view of required accuracy of charging. From the characteristic, injection energy to be used is set up and initial irradiation energy Vi of the electron source 28 is set up (step 104). Then, a target voltage Vc for charging is set up (step 105), a signal representing irradiation energy change is sent from the waveform generator 24 to the electron source controller 23, and the irradiation energy of the electron source 28 is changed toward the target voltage Vc (step 106). At this time, the charging efficiency during electron beam irradiation is measured, while monitoring for a leak current is performed. While the charging efficiency being 1 is monitored by an operational unit installed in the waveform generator 24, the speed of changing the irradiation energy is adjusted (step 107). At this time, the charging efficiency is not limited to 1, but it is preferred to monitor charging efficiency of 0.8 or more in view of required accuracy of charging, as noted previously. Although the method of changing the irradiation energy of the electron source 28 is used in the present exemplary embodiment, there is an alternative method of controlling a voltage that is applied to the specimen or controlling an irradiation angle. As for the voltage pitch of change of irradiation energy, irradiation energy must be changed by a pitch that falls within the injection energy band from El to Eh. However, if El is 0 eV, irradiation energy change may be continuous, as shown in FIG. 4 above. When charging is completed, the conditions of the electron optical system are set up as specimen observation conditions (step 108). At this time, it is preferable that the charging voltage of the specimen is fed back to the electron gun controller 13 and irradiation energy during observation is adjusted. During observation, it is preferable to set up conditions such that the surface charging state of the specimen is hard to change and an electron beam scanning method, additive processing, etc. are also effective. Observation of the specimen using voltage contrast is performed (step 109) and, after the observation, the specimen is unloaded from the electron microscope by the specimen transport system 11 (step 110).

In the present exemplary embodiment, the procedure of measuring injection energy for which high charging efficiency is attained for each specimen is adopted, as in steps 103, 104 above. However, it is also possible that appropriate injection energy according to the material, film thickness, and manufacturing process of a specimen is put into a database and, each time a specimen is observed, corresponding injection energy is loaded from the database stored in the data storage unit 27 through the control computer 25 and set up. Moreover, because injection energy for many types of material falls within the range from 0 eV to 10 eV, steps 103 and 104 above can be dispensed with by setting up initial irradiation energy at 0 V. When irradiation energy is changed from the state that the injection energy is 0 eV, initial charging of a specimen is important. It is preferable to measure an initial voltage of the surface of a specimen beforehand or discharge the specimen. However, if the initial voltage is unknown, a method of changing irradiation energy from a range of irradiation energy driving back an electron beam is also effective.

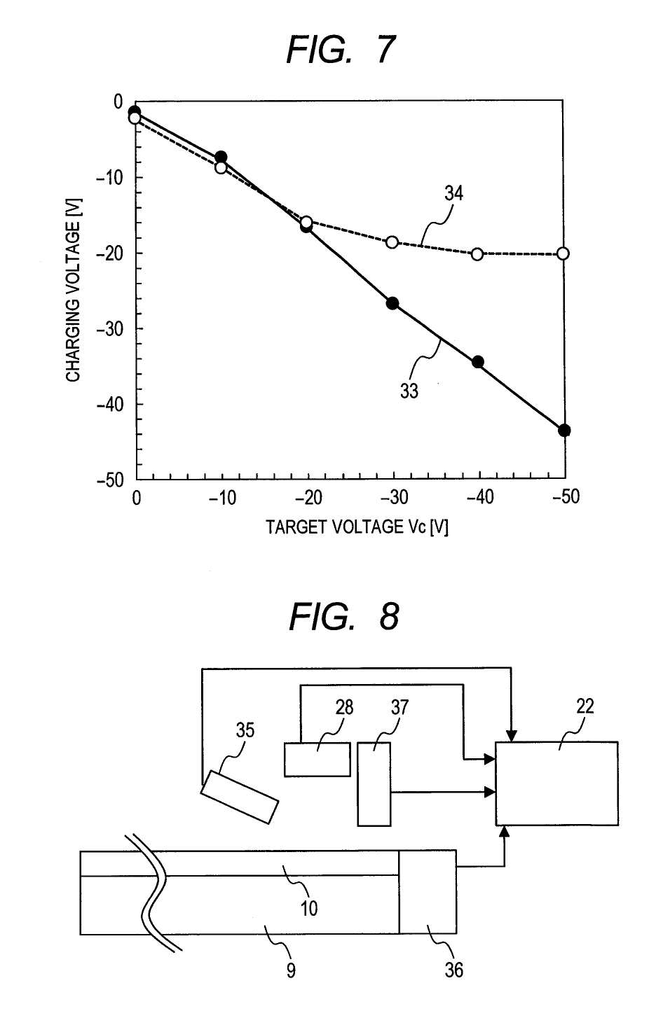

When charging of a resist film has been performed by following the flowchart, a result of comparison between a target voltage and a charging voltage at which the specimen could be charged is shown in FIG. 7. A measurement result 33 is a result of charging by using the present exemplary embodiment. It can be seen that the specimen can be charged in accordance with the target voltage Vc and well-controlled charging can be achieved. On the other hand, a measurement result 34 is a result of charging by a related-art charging method which first sets up irradiation energy at the target voltage Vc and performs charging. The measurement result 33 shows that charging from 0 V to −50 V can be controlled, whereas the measurement result 34 shows that the specimen can only be charged up to −20 V. In this way, the present exemplary embodiment, if used, enables well-controlled, high-density charge accumulation on a specimen and specimen observation with a high image quality.

### Second Embodiment

In the present exemplary embodiment, descriptions are provided about a method and apparatus that set up a speed of change of irradiation energy from the capacitance of a specimen. FIG. 8 shows a specimen charging system that implements the present exemplary embodiment. The specimen charging system is configured with an electron source for specimen charging 28, an ellipsometer 35 that can measure the electric permittivity and thickness of a specimen, a knife-edge ammeter 36 that can measure the irradiation current and irradiation area of an electron beam for charging, and a surface potential meter 37. In the present exemplary embodiment, the speed of change of irradiation energy is defined as the slope of change of irradiation energy a (target voltage/time taken for change). The slope of change of irradiation energy a must be set equal to or less than a slop threshold in equation (2).

Slope threshold=irradiation current/specimen capacitance (2)

Specimen capacitance is obtained by equation (3).

Specimen capacitance=electric permittivity of specimen×irradiation area/specimen thickness (3)

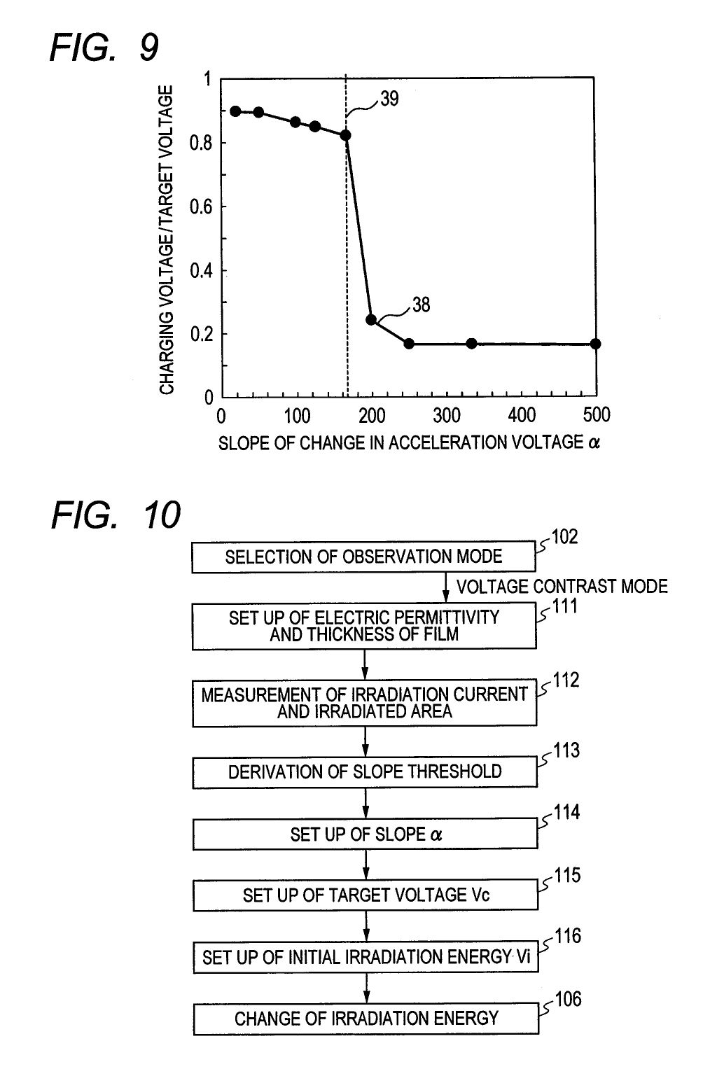

In the present exemplary embodiment, the effect of the slope of change of irradiation energy α is described, taking an SiO2 specimen of a film formed on an Si substrate as an example. FIG. 9 shows a relationship between the slope of change of irradiation energy α and specimen charging voltage 38, when the target voltage is set at −50 V and irradiation energy is changed from 0 V to the target voltage. Charge of the specimen was measured by the surface potential meter 37. The charging voltage was normalized by the target voltage Vc. In the figure, the position of the slope threshold 39 in accordance with equations (2), (3) was shown. When charging was performed with the slope of change α being equal to or less than the slope threshold 39, charging at a high efficiency where charging voltage/target voltage is 0.8 or more is attainable. Whereas, when the slope of change α is more than the slope threshold 39, the chargeable level is only less than a half of the target voltage. In the case that the slope of change α is more than the slope threshold 39, the amount of charges of irradiation onto the specimen is insufficient and, thus, the charging voltage of the specimen cannot rise. Therefore, the injection energy increases with changing of the irradiation energy and this results in a decrease in the charging efficiency and high-density charge accumulation is impossible. If the slope of change α is equal to or less than the slope threshold 39, a sufficient amount of charges of irradiation is gained and the injection energy is maintained within an injection energy band for which high charging efficiency is attained. Thus, high-density charge accumulation becomes possible.

A flowchart describing a method for setting up a slope threshold according to the present exemplary embodiment is shown in FIG. 10. After selection of an observation mode was performed as in step 102 in FIG. 6 above, the electric permittivity and thickness of a specimen are measured by the ellipsometer 35 in order to determine the capacitance of the specimen (step 111). Also, the irradiation area and irradiation current are measured by the knife edge ammeter 36 (step 112). A slope threshold 39 is calculated from equations (2), (3) above (step 113). A slope of change α that is equal to or less than the slope threshold 39 is set up (step 114), a target voltage Vc for charging is set up (step 115), and initial irradiation energy Vi is set up (step 116). In the present exemplary embodiment, the initial irradiation energy Vi is set at 0 V, because the injection energy band for which no charges flow out from the SiO2 specimen is from 0 eV to 5 eV. Step 106 in FIG. 6 above is executed and, subsequently, charging and observation are performed according to the flowchart of FIG. 6. Although, as the slope of change α, any value that is equal to or less than the slope threshold 39 can be set up, it is preferable to set up the slope of change α to a value that is at the same level as the slope threshold 39 in view of a speed of charging. If the slope of change was set to a value that is at the same level as the slope threshold 39, the slope threshold 39 changes with changing over time of the irradiation current. Therefore, it is preferable to set up the slope of change of irradiation energy, taking account of a change in the irradiation current, or use a method that measures a change in the irradiation current during charging and controls the slope of change α of irradiation energy as a function of a change of the slope threshold 39. It is also possible that a slope threshold 39 set up by the flowchart of the present exemplary embodiment is put into a database stored in the data storage unit 27 and loaded for use later whenever required.

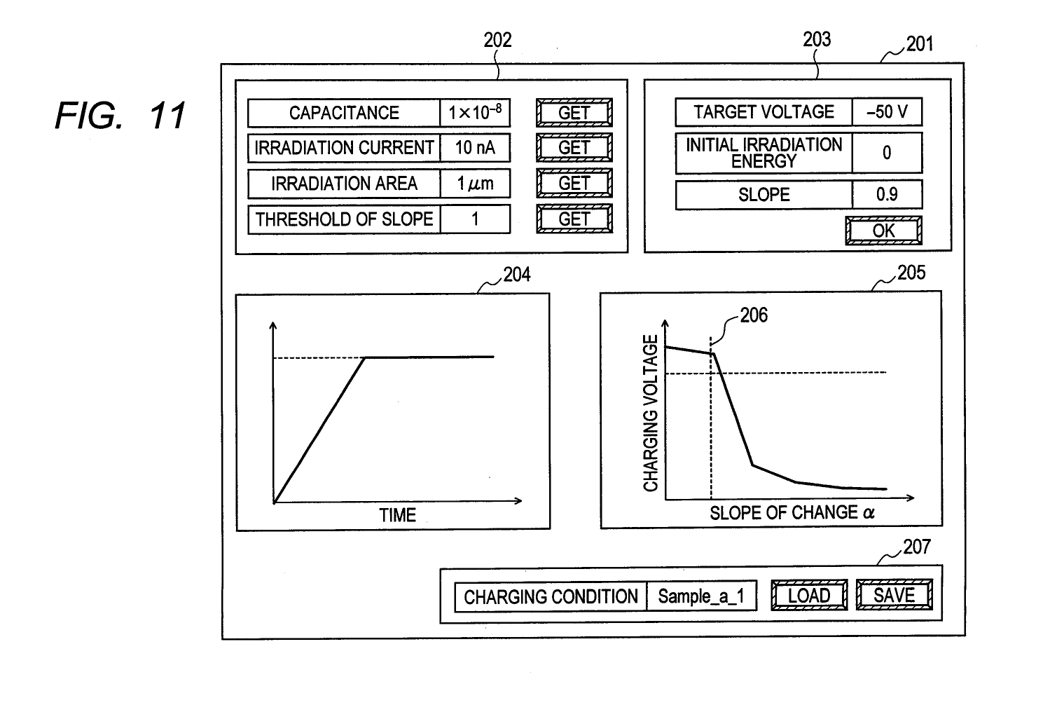

A GUI that facilitates condition setting of the present exemplary embodiment is shown in FIG. 11. After selection of an observation mode as in step 102 in FIG. 6 above, a charging execution GUI 201 is displayed on the control computer 23. In a window 202, the parameters mentioned as in the above steps 111, 112 are obtained and a slope threshold 39 can be calculated. In a window 203, a sequence of charging can be set, as in the above steps 114, 115, 116. The sequence of charging as set at this time is displayed in a window 204. Besides, in a window 205, an effect like that shown in FIG. 9 above can be verified. A dashed line 206 in the window 205 is the slope threshold 39. These results can be stored into the data storage 27, using a window 207, and the stored sequence can be loaded for use later when charging of a specimen of the same type is performed.

### Third Embodiment

In the present exemplary embodiment, descriptions are provided about a method and apparatus that handle a specimen having a large charging area. The apparatus structure is the same as shown in FIG. 1 above. In a case where charging of a large specimen is performed, charging wider than an electron beam irradiation area is performed by a method of scanning the specimen with the electron source for charging. In the present exemplary embodiment, scanning is to be controlled by movement of the XYZ stage 8 on which the specimen holder is mounted. Scanning can also be controlled by movement of the electron source for charging. In the present invention, time taken for a single change of irradiation energy must be equal to or less than the rapidity of movement of the irradiation area. That is, a threshold of stage velocity Vlim is determined by equation (4).

Vlim=irradiation area of electron source for charging/time Tr taken for a single change of irradiation energy (4)

Time Tr taken for a single change of irradiation energy is determined by equation (5).

Tr=(target voltage Vc−initial irradiation energy)/slope of change of irradiation energy (5)

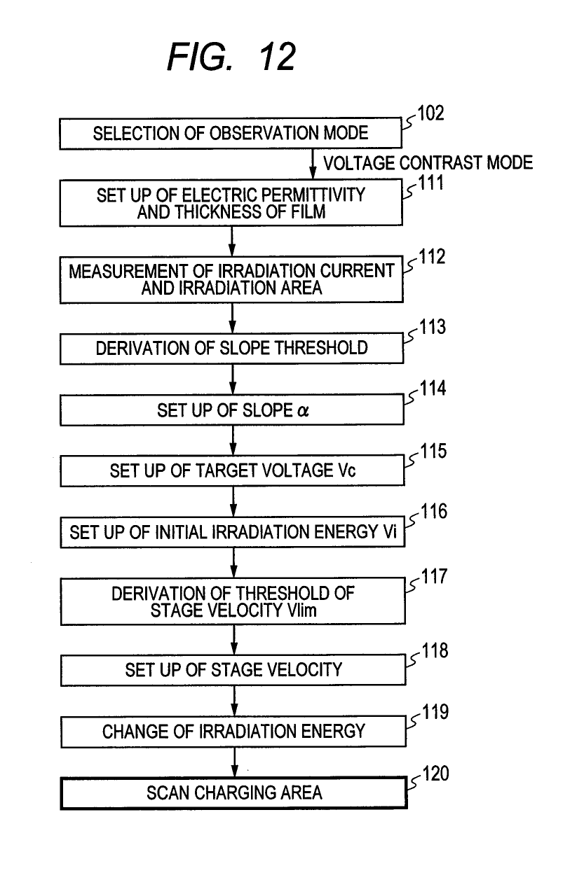

A flowchart describing a charging method according to the present exemplary embodiment is shown in FIG. 12. According to the flowchart of FIG. 10 of the preceding exemplary embodiment, setup of a slope of change of irradiation energy α (step 114), setup of a target voltage Vc (step 115), and setup of initial irradiation energy Vi (step 116) are performed. Then, a threshold of stage movement velocity Vlim is calculated from equations (4), (5) above (step 117). The stage velocity is determined so that it will be equal to or less than the calculated velocity threshold Vlim (step 118). In this regard, at any velocity that is equal to or less than the velocity threshold Vlim, the present exemplary embodiment can be carried out. However, it is preferable to set up a stage velocity that is at the same level as the velocity threshold Vlim in view of a speed of charging. Thereafter, the irradiation energy is changed according to the set-up parameters (step 119) and a desired charging area is scanned by moving the stage at the set-up stage velocity (step 120). After the charging is completed, step 108 and subsequent steps described in FIG. 6 above are executed and the specimen observation is performed. According to the present exemplary embodiment, high-density charge accumulation on a specimen having a large charging area can be implemented.

According to the present exemplary embodiment, high-density charge accumulation on a specimen having a large charging area is possible by taking account of a slope of change of irradiation energy α and a stage velocity.

### Fourth Embodiment

In the present exemplary embodiment, descriptions are provided about another method and apparatus that handle a specimen having a large charging area. In the present exemplary embodiment, irradiation energy when charging is controlled is changed in steps on a voltage pitch basis. A charging area is to be scanned by moving the stage per irradiation energy step. The apparatus structure is the same as shown in FIG. 1 above. According to this method, because there is no need for changing irradiation energy, while forming an irradiation area, charging can be performed independently of the control speed of the charging controller 22.

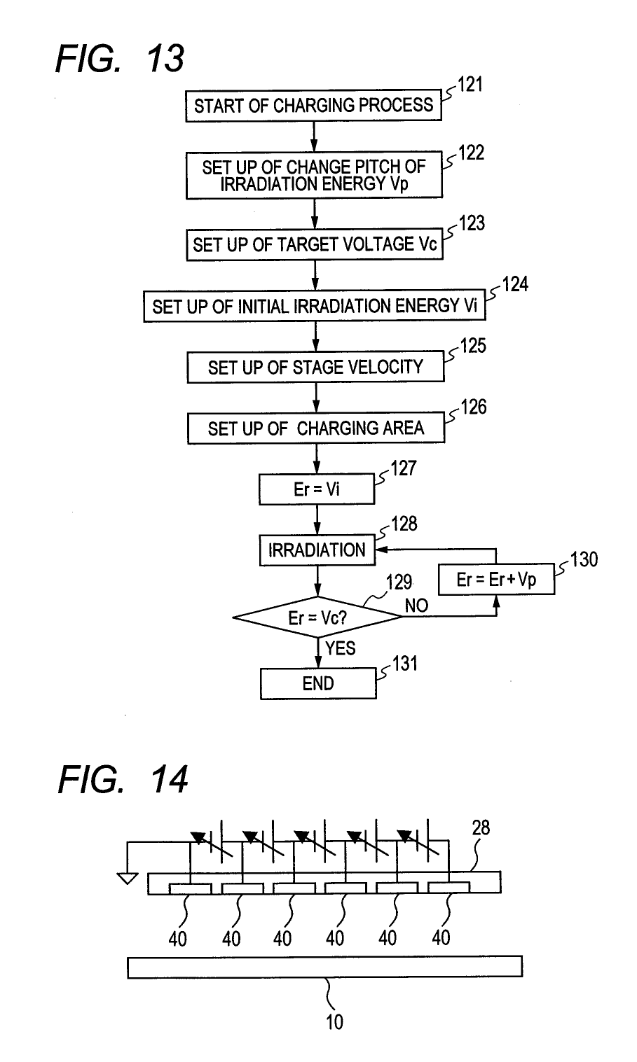

Details are described, based on a flowchart of FIG. 13. When a voltage contrast mode is selected, the apparatus enters a charging execution mode (step 121). First, a change pitch (in voltage) of irradiation energy Vp is set up for making a stepwise change of irradiation energy (step 122). The change pitch (in voltage) of irradiation energy Vp falls within an injection energy band from El to Eh shown in FIG. 3. Then, a target voltage Vc and initial irradiation energy Vi are set up (steps 123, 124). A stage movement velocity allowing that the irradiated specimen can gain sufficient charges with a charging voltage in a single step of irradiation is preferable (step 125). After a charging area is in turn set up (step 126), charging is executed. Charging the whole charging area with the initial irradiation energy Vi is first performed by moving the stage at the set-up stage velocity (steps 127, 128). If the irradiation energy Er does not reach the target voltage Vc after charging the whole area, the irradiation energy is increased by a voltage pitch Vp (steps 129, 130). Charging the whole charging area is performed again and this process is repeated until the target voltage Vc has been reached. Once the irradiation energy Er has increased up to the target voltage Vc, the charging process is completed (step 131).

According to the present exemplary embodiment, charging independent of the performance of the charging controller 22 is possible and high-density charge accumulation can be performed with ease.

### Fifth Embodiment

In the present exemplary embodiment, descriptions are provided about a charging method other than changing irradiation energy and associated apparatus. Although the apparatus structure is the same as shown in FIG. 1 above, an electron source that allows a change in irradiation energy within an irradiation area is used as the electron source for charging in the charging system. An example of the electron source that allows a change in irradiation energy within an irradiation area is shown in FIG. 14. The electron source for charging 28 is configured with electron sources 40, for each of which irradiation energy can be controlled. Since initial irradiation energy is often −5V and a target voltage Vc falls within −50 V in most cases, it is preferable that the electron source is constituted by roughly ten electron sources 40. In that case, injection energy of −5 V, −10 V, −15 V, . . . −45 V, −50 V are applied to the divisional electron sources 40 in order from left. Then, a specimen can be charged by relative movement of the electron sources 40 toward the left with respect to the specimen 10, while maintaining injection energy for which high charging efficiency is attained.

As another arrangement, the electron sources 40 in FIG. 14 above are formed of resistors instead of power sources, and irradiation energy distribution can be controlled by letting current flow through them. In that case, even if a single electron source is used, by letting electrons pass through the resistors in an irradiation energy application unit, irradiation energy distribution can be controlled in the same manner as described previously. If the electron source for charging of the present exemplary embodiment is used, the process of changing irradiation energy is dispensed with, and the charging speed is not restricted by a slope of change a; thus, high-speed processing can be performed.

### REFERENCE SIGNS LIST

1 Electron microscope
2 Electron gun
3 Condenser lens
4 Alignment coil
5 Deflector
6 Objective lens
7 Detector
8 XYZ stage
9 Specimen holder
10 Specimen
11 Specimen transport unit
12 Evacuation unit
13 Electron gun controller
14 Condenser lens controller
15 Alignment coil controller
16 Deflection controller
17 Objective lens controller
18 Detector controller
19 Detected signal processing unit
20 Stage controller
21 Evacuation controller
22 Charging controller
23 Electron source controller
24 Waveform generator
25 Control computer
26 Display unit
27 Data storage unit
28 Electron source for charging
29 Ammeter
30 Faraday cup
31 Time chart of irradiation energy
33 Charging voltage produced by the present invention
34 Charging voltage produced by a related-art method
35 Ellipsometer
36 Knife-edge ammeter
37 Surface potential meter
38 Charging voltage when slope changes
39 Slop threshold
40 Electron source
201 Charging execution GUI
202, 203, 204, 205, 207 Window
206 Slop threshold

1. A method for observing a specimen using an electron beam by making an electron beam strike on a specimen and detecting electrons ejected from the specimen, comprising:
charging the specimen by irradiating the specimen with an electron beam having a first injection energy band for which high charging efficiency is attained in a low injection energy range; and
after charging the specimen, irradiating the specimen with an electron beam having second injection energy and performing an observation of the specimen using voltage contrast.

2. The method for observing a specimen using an electron beam according to claim 1, wherein:
the charging the specimen comprises changing irradiation energy of the electron beam up to a target voltage for charging, while maintaining the injection energy of the electron beam having the first injection energy.

3. The method for observing a specimen using an electron beam according to claim 1, wherein:
the charging the specimen comprises changing irradiation energy of the electron beam up to a target voltage for charging, while monitoring for a current flowing from the specimen during irradiation with the electron beam having the first injection energy.

4. The method for observing a specimen using an electron beam according to claim 2, wherein:
a speed of changing the irradiation energy is set equal to or less than a threshold that is determined from electrostatic capacitance of the specimen and an irradiation current.

5. The method for observing a specimen using an electron beam according to claim 2, wherein:
the method further comprises the step of charging a specimen having a large charging area by scanning the specimen with the electron beam and a speed of scanning the specimen with the electron beam is set depending on a speed of changing the irradiation energy.

6. The method for observing a specimen using an electron beam according to claim 3, wherein:
the changing irradiation energy of the electron beam up to a target voltage for charging comprises:
scanning the specimen with the electron beam having the first injection energy;
changing irradiation energy of the electron beam by a voltage pitch that maintains the first injection energy;
irradiating again the specimen with the electron beam and by the changed irradiation energy of the electron beam;
scanning again the specimen with the electron beam having the first injection energy;
charging the specimen having a large charging area up to a target voltage for charging by repeating the steps of changing irradiation energy of the electron beam, irradiating the specimen with the electron beam, and scanning the specimen.

7. The method for observing a specimen using an electron beam according to any one of claim 2, wherein:
the first injection energy band or the first injection energy is from 0 to 10 eV.

8. The method for observing a specimen using an electron beam according to claim 2, wherein:
the charging efficiency is equal to or more than 0.8.

9. An electron microscope comprising:
an electron gun that emits an electron beam;
an electron optical system that irradiates a specimen with the electron beam;
a specimen holder that holds the specimen;
a detector that detects electrons ejected from the specimen;
a second electron source for which irradiation energy can be controlled;
a waveform generator that generates a changing waveform of irradiation energy; and
an irradiation energy controller that changes irradiation energy of an electron beam of the second electron source, while maintaining injection energy that falls within an injection energy band for which high charging efficiency is attained during electron beam irradiation, based on the changing waveform of irradiation energy.

10. An electron microscope comprising:
an electron gun that emits an electron beam with controlled irradiation energy;
an electron optical system that irradiates a specimen with the electron beam;
a specimen holder that holds the specimen;
a detector that detects electrons ejected from the specimen;
a charging efficiency measurement device that measures charging efficiency of the electron beam;
a waveform generator that generates a changing waveform of irradiation energy; and
an irradiation energy controller that changes irradiation energy of the electron beam, while maintaining injection energy that falls within an injection energy band for which high charging efficiency is attained during electron beam irradiation, based on the changing waveform of irradiation energy and depending on a measurement result of the charging efficiency.

11. The electron microscope according to claim 9, further comprising a charging efficiency measurement device that measures charging efficiency of an electron beam from the second electron source.

12. The electron microscope according to claim 9, wherein:
the irradiation energy controller controls a voltage that is applied to the electron source of an electron beam and a voltage that is applied to the specimen.

13. The electron microscope according to claim 9, wherein:
the electron microscope further comprises a moving mechanism that moves the specimen holder and the moving mechanism comprises a velocity controller that sets up a velocity of moving the specimen holder, based on the changing waveform from the irradiation energy controller, and a stage mechanism that moves the specimen holder according to the set-up velocity.

14. The electron microscope according to claim 10, wherein:
the charging efficiency measurement device comprises an irradiation current ammeter that measures an irradiation current and a surface potential meter that measures a charging voltage during electron beam irradiation.

15. The electron microscope according to claim 9, wherein:
The second electron source for which irradiation energy can be controlled is an electron source divided into a plurality of elements to which steps of irradiation energy from initial irradiation energy up to a target voltage are applied in order; and
the electron microscope further comprises a moving mechanism that causes relative movement of the specimen holder and the electron source at such a velocity as to maintain injection energy that falls within an injection energy band for which high charging efficiency is attained during electron beam irradiation.

16. The electron microscope according to claim 10, wherein:
the irradiation energy controller controls a voltage that is applied to the electron source of an electron beam and a voltage that is applied to the specimen.

17. The electron microscope according to claim 10, wherein:
the electron microscope further comprises a moving mechanism that moves the specimen holder and the moving mechanism comprises a velocity controller that sets up a velocity of moving the specimen holder, based on the changing waveform from the irradiation energy controller, and a stage mechanism that moves the specimen holder according to the set-up velocity.

18. The electron microscope according to claim 11, wherein:
the charging efficiency measurement device comprises an irradiation current ammeter that measures an irradiation current and a surface potential meter that measures a charging voltage during electron beam irradiation.
